(19) United States
(12) Patent Application Publication
(10) Pub. No.: US 2004/0175963 A1
(43) Pub. Date: Sep. 9, 2004

(54) Production of electronic devices by solution processing

(75) Inventors: Paul A. Cain, Cambridge (GB); Nicholas J Stone, Cambridge (GB)

Correspondence Address: SUGHRUE MION, PLLC, 2100 PENNSYLVANIA AVENUE, N.W., SUITE 800, WASHINGTON, DC, 20037, US

(73) Assignee: PLASTIC LOGIC LIMITED

(21) Appl. No.: 10/793,225

(22) Filed: Mar. 5, 2004

(30) Foreign Application Priority Data
Aug. 5, 2003 (GB) 0318349.8
Mar. 8, 2003 (GB) 0305377.4

(51) Int. Cl. H01L 21/00

(52) U.S. Cl. 438/800; 438/758

(57) ABSTRACT

Production of an electronic device by solution processing by depositing fluid including a device material or a precursor thereto onto a zone of a substrate surface between at least two opposed barriers for together controlling the spread of said fluid on the substrate surface, wherein at least one of the two opposed barriers is structured so as to facilitate controlled spillage of excess fluid out of the zone to one or more selected locations. Also, production of an electronic device by solution processing by longitudinally depositing fluid containing a device material or a precursor thereto on a patterned substrate to form a plurality of spaced longitudinal channels of said device material of controlled lateral width, wherein the substrate is patterned such that at least one lateral connection between at least one pair of adjacent channels is formed at at least one selected location without the need to carry out any lateral deposition of said fluid.

### FIELD OF THE INVENTION

This invention relates to the production of electronic devices by solution processing.

### BACKGROUND OF THE INVENTION

Solution processing technology is ideally suited for the relatively inexpensive production of relatively large area electronic devices and is compatible with the use of flexible, plastic substrates.

In WO01/47043, whose content is incorporated herein by reference, a method is described by which high performance transistors with well-defined and controlled channel lengths of less than 10 μm can be fabricated by solution processing in combination with direct printing.

With reference to FIG. 1, the method described in WO01/47043 involves the use of barriers 2 (particuarly, relatively hydrophobic regions) on the substrate 1 to control the spread of droplets 4 deposited on the subtrate (either from directly over the surface areas between the barriers as shown in FIG. 1A, or from directly over the hydrophobic barriers as shown in FIG. 1B) and thereby form features 5 with relatively high resolution. A semiconductor layer 6, an insulator layer 7 and a gate electrode 8 are then formed to complete the TFT structure as shown in FIG. 1C.

One of the considerations with this technique is the avoidance of fluid spilling into unwanted areas, such as for example the avoidance of conductive material used to form the drain and source electrodes of a transistor device from spilling into the channel separating the electrodes. This is of particular concern where it is important to form features (such as drain and source electrode) with a minimum height.

### SUMMARY OF THE INVENTION

It is an aim of the present invention to provide a technique of effectively avoiding the spillage of deposited fluid into unwanted areas, and in particular to provide a technique by which spillage into unwanted areas can be avoided whilst allowing the desired minimum feature height to be achieved reliably.

It is an independent aim of the present invention to provide a technique for forming at least one electrical interconnection between a plurality of features formed by the longitudinal deposition of droplets on a substrate.

According to one aspect of the present invention, there is provided a method of producing an electronic device by solution processing according to claim 1 or claim 4, and a substrate for use in the production of an electronic by solution processing according to claim 8 or claim 9.

In one embodiment, the method involves incorporating narrow spew points in non-critical areas of the barriers, that allow ink to spread into a selected location of the substrate. Excess ink is thus automatically directed to a non-critical area without overspilling into a critical-area, such as an area where it would generate an undesirable electrical short. The printing is thus made to be less critically dependent on the amount of deposited ink, and on the detailed printing parameters.

According to another aspect of the present invention, there is provided a method of producing an electronic device by solution processing according to claim 11, and a substrate for use in producing an electronic device by solution processing according to claim 14.

Features of specific embodiments of the present invention are defined in the dependent claims.

In one embodiment, a regular array of surface energy patterns is provided that would allow a plurality of circuits to be printed within the wells defined by the pattern, so that all the circuit design can be done at the inkjet printing stage; the surface energy patterning stage is completely generic.

### BRIEF DESCRIPTION OF THE DRAWINGS

An embodiment of the present invention will now be described, by way of example only, with reference to the accompanying drawings, in which:

FIG. 1 illustrates the known technique of surface-energy assisted, high-resolution printing of a transistor device;

FIG. 2 illustrates a technique according to an embodiment of the present invention;

FIG. 3 shows how the contact angle between ink deposited on a substrate between two hydrophobic lines increases as the volume of ink increases;

FIG. 4 shows a microscope image of inkjet printed lines produced by a technique according to an embodiment of the present invention;

FIG. 5 shows a microscope image of inkjet printed PEDOT transistor channels defined and interconnected on a generic surface-energy patterned substrate according to an embodiment of the technique of the present invention.

### DESCRIPTION OF PREFERRED EMBODIMENTS

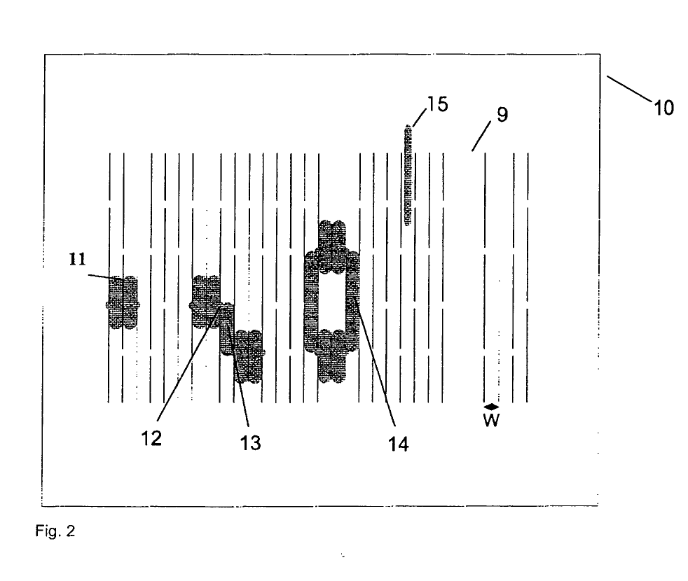

FIG. 2 shows a number of TFT device features formed by longitudinal deposition of droplets onto a generic surface-energy patterned substrate according to one embodiment of the technique of the present invention. The thin lines 9 are made of a hydrophobic material (such as polyimide) deposited on top of a hydrophilic substrate 10 (such as glass). The hydrophobic lines may be ˜10 μm wide or much narrower, and will define the channel (length) between adjacent drain and source lines of a TFT. The separation W between neighbouring parallel hydrophobic lines (i.e. the width of the wells) is likely to be φ, where φ is the diameter of an ink drop on the hydrophilic surface.

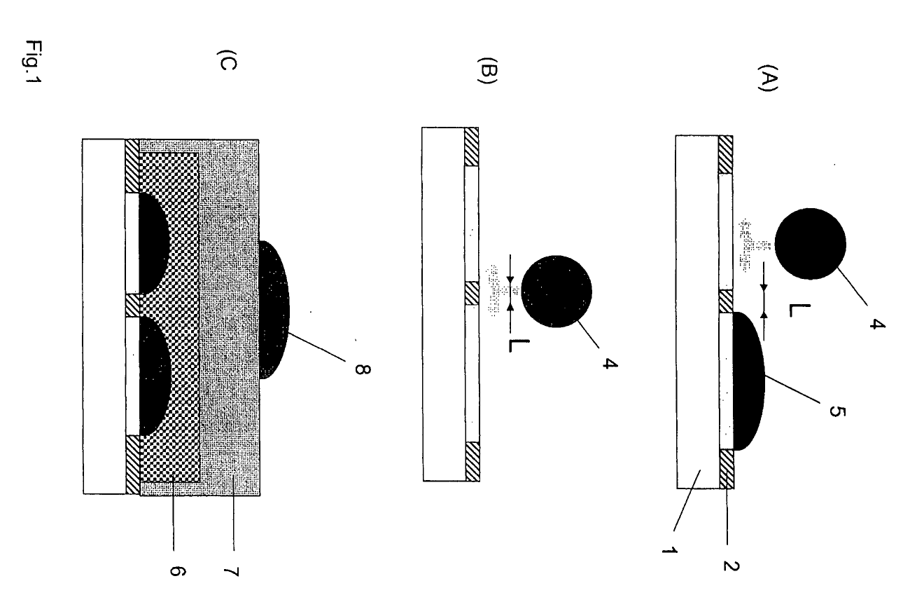

Although not shown in FIG. 2, a semiconductor layer would then be formed over the drain and source lines, followed by an insulator layer and a gate electrode, as shown in FIG. 1(C), to complete the TFT structure.

Printing into the well formed by two adjacent hydrophobic lines will form a continuous pool of ink that touches both hydrophobic lines (since the well width is less than the diameter of the ink drop on an unconfined surface). Printing in two adjacent wells allows a well defined gap 11 to be formed between the two ink pools, so that a transistor can be formed. Printing into a well where a gap in the hydrophobic line exists 12 (spew point), allows ink to leak through into a neighbouring hydrophilic surface region, allowing it to form electrical interconnections to the material deposited inside the adjacent well. These spew points act as pressure release valves for the deposited ink. Once a region of the well is full of liquid, the first place the liquid will burst out of the well is at the spew point, ensuring that the TFT channel is not damaged. Adjusting the width of the spew point allows the pressure tolerance of the wells to be controlled: a wider spew point gives a lower bursting pressure.

The spew points are also used in some locations to interconnect two neighbouring wells. The main advantage of this is that no horizontal interconnects are required to link neighbouring transistors together, so that all printing can be performed in one direction. FIG. 2 shows how two transistors can be interconnected 13 so that the source of one is connected to the drain of the other. The separation of the two transistors is approximately a single well width W in distance (or a single drop in diameter).

The brickwork nature of the surface-energy pattern allows transistors of different channel widths to be formed 14, and the interconnection of transistors to be done very space-efficiently, using the spew points to form electrical connections. The pattern shown in FIG. 2 is particularly suited for design of printed logic circuits, as it allows fabrication of arbitrary transistor layouts, with the only constraints imposed being that (a) the channel of each transistor of length L is aligned with one of the hydrophobic barriers of width L, and (b) the electrical interconnections between electrodes and interconnects in surface regions separated by a hydrophobic barrier are made in the region of a spew point.

The conductivity of interconnect lines that run along the wells (i.e. they are not to cross the hydrophobic barriers) can be increased by printing many subsequent lines each over the top of the previous. In order to prevent the ink spilling over the hydrophobic barriers the printing speed is increased so that less ink is deposited per unit length of well. The printing speed determines the width of the printed line on an unconfined substrate. By using the appropriate speed lines 15 that are narrower than the well can be printed and lines overprinted many times (and therefore with lower resistance) can be created along the length of the wells.

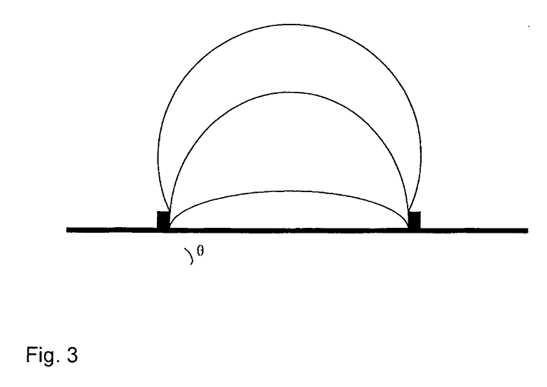

As shown schemtically in FIG. 3, in the absence of a spew point the contact angle θ increases with ink volume, until eventually the ink will burst over the hydrophobic line. By adding a spew point somewhere along one of the polyimide lines, the ink preferentially flows through the spew point rather than over the hydrophobic line. This gives a more reproducible level of ink fill (and so contact angle) for a wider range of ink volumes.

The pitch of the wells can be chosen so that it is a multiple of the pitch of inkjet nozzels on a multinozle inkjet head (although the pitch of nozzles on a head can be varied on the fly by raking or rotating the head away from perpendicular to the direction of travel). If the pitch of the wells were to be 63.5 um and the multinozzle inkjet head was 100 dpi then for each pass of the head over the substrate a quarter of the chip would be passed over by a nozzle. In this way and by stepping the head by a well pitch it would take just four passes of the head over the chip to print an entire chip. This assumes that the print head is larger in width than the chip.

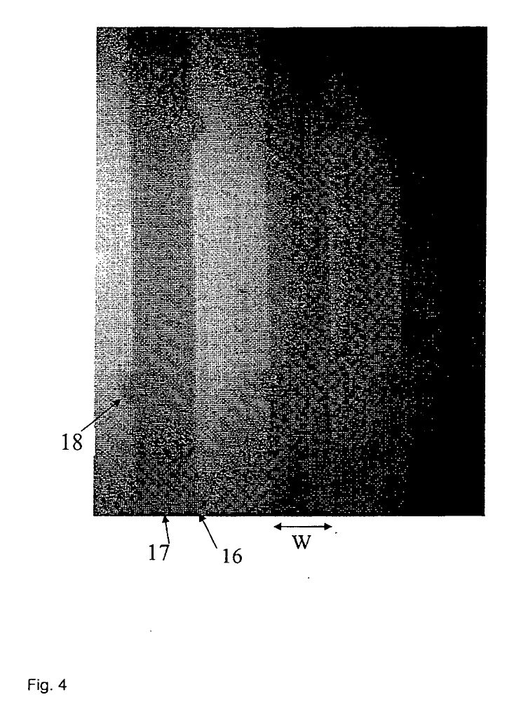

FIG. 4 shows an image of features formed by the longitudinal deposition of droplets on a patterned glass substrate according to an embodiment of the technique of the present invention. The hydrophobic lines 16 are 5 μm wide and spaced by 100 μm (well width W) on the hydrophilic glass substrate. A solution of electrically conductive PEDOT/PSS was printed into the wells 17 at a firing frequency of 500 Hz. The linear speed of the head passing over the substrate was adjusted to ensure the wells were sufficiently filled without bursting (execpt through the spew point 18).

The droplet volume used was 16 pl and the substrate speed was 22 mm/s. This gave a distance between drops on the substrate of 44 um and a volume of ink of 295 pl along a 100 um wide well. Spew points were seperated by a distance of 340 um on alternate sides of the well and were 50 um wide. For a line along the well of length 340 um (where only one spew point is present) there will be 100 pl of ink. The pool of ink that exits through a spew point occupies (on the other side of the spew point in the adjacent well) an area of 40 um×50 um, assuming the same volume of ink per unit length as the channel, the volume of spewed ink is approximately 6 pl. Therefore the volume of ink in the channel is reduced by ˜6%.

The presence of PEDOT at spew points 18 on either side of the well shows that the well is completely filled with PEDOT. The equal size of the PEDOT region at the spew points on either side of the channel suggests that the inkjet printing of the PEDOT was done centrally over the channel, showing that alignment is good.

Three PEDOT lines printed on a generically surface-pattemed glass substrate are shown. The dark regions 17 are the wells filled with PEDOT. The spew points 18 can clearly be seen, and are of a repeatable size. The presence of spew points of the same size on either side of the well indicates that the wells are fully fillIed, and that the PEDOT is being deposited centrally into the well. The spew points are 50 μm gaps in the polyimide lines.

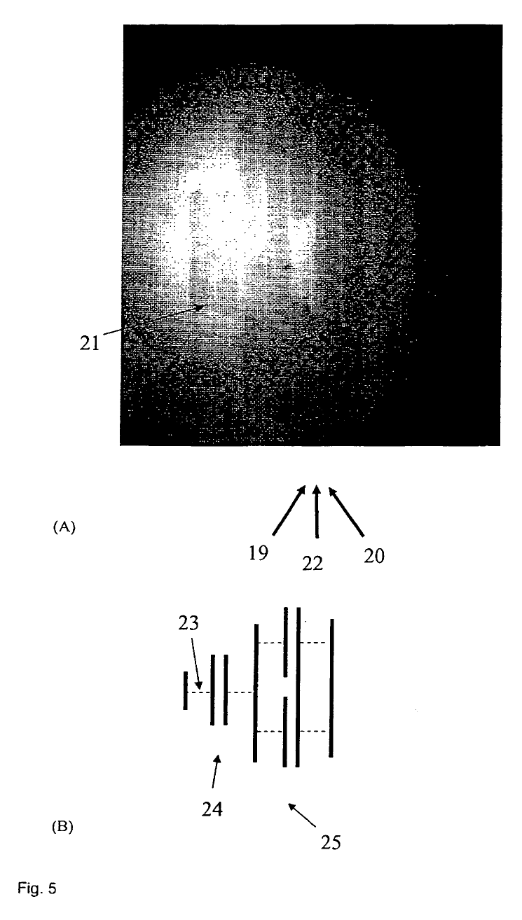

FIG. 5B shows a schematic of the logical inverter shown in FIG. 5A. FIG. 5A shows just the source and drain level printing, and so transistors are represented in the schematic shown in FIG. 5B as capacitors,. The spew point interconnects are shown as dashed lines 23. The circuit consists of a small input transistor 24 and a larger load transistor 25 (two transistors in parrallel).

FIG. 5A shows an array of lines forming the source(19)-drain(20) electrodes of a logical inverter circuit. The spew points 21 can be seen to join a respective pair of two adjacent lines together, and in the absence of a spew point, a transistor channel is formed between adjacent lines (three places within the array of lines). Where the spew point is not present between adjacent lines (3 places within the array of printed lines), a transistor channel 22 is formed. This pattern forms the lower layer of a logical inverter. Similar techniques can be used for surface-energy assisted printing of electrodes and interconnects for more complex logic circuits.

The processes and devices described herein are not limited to devices fabricated with solution-processed polymers. Some of the conducting electrodes of the TFT and/or the interconnects in a circuit or display device (see below) may be formed from inorganic conductors, that can, for example, be deposited by printing of a colloidal suspension.

In a preferred embodiment, a solution processible conjugated polymeric or oligomeric material that exhibits adequate field-effect mobilities exceeding 10⁻³ cm²/Vs, preferably exceeding 10⁻² cm²/Vs is used for the TFT semiconductor layer to be deposited over the drain and source electrodes. Examples of suitable materials are reviewed for example in H. E. Katz, J. Mater. Chem. 7, 369 (1997), or Z. Bao, Advanced Materials 12, 227 (2000). Other possibilities include small conjugated molecules with solubilising side chains (J. G. Laquindanum, et al., J. Am. Chem. Soc. 120, 664 (1998)), semiconducting organic-inorganic hybrid materials self-assembled from solution (C. R. Kagan, et al., Science 286, 946 (1999)), or solution-deposited inorganic semiconductors such as CdSe nanoparticies (B. A. Ridley, et al., Science 286, 746 (1999)).

Ink-jet printing of the electrodes is considered to be particularly suitable for large area patterning with good registration, in particular for flexible plastic substrates.

Although preferably all layers and components of the device and circuit are deposited and patterned by solution processing and printing techniques, one or more components may also be deposited by vacuum deposition techniques and/or patterned by a photolithographic process.

Devices such as TFTs fabricated as described above may be part of a more complex circuit or device in which one or more such devices can be integrated with each other and or with other devices. Examples of applications include logic circuits and active matrix circuitry for a display or a memory device, a sensing device or a user-defined gate array circuit.

The patterning process may be used to pattern other components of such circuit as well, such as interconnects, resistors, capacitors etc.

The present invention is not limited to the foregoing examples. Aspects of the present invention include all novel and/or inventive aspects of the concepts described herein and all novel and/or inventive combinations of the features described herein.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

What is claimed is:

1. A method of producing an electronic device by solution processing, the method including the step of depositing fluid including a device material or a precursor thereto onto a zone of a substrate surface between at least two opposed barriers for together controlling the spread of said fluid on the substrate surface, wherein at least one of the two opposed barriers is structured so as to facilitate controlled spillage of excess fluid out of the zone to one or more selected locations.

2. A method according to claim 1, further including the step of depositing an excessive level of fluid onto the zone so as to cause spillage of fluid out of the zone to the one or more selected locations, thereby controlling the level of fluid in the zone whilst avoiding spillage of fluid to undesired locations.

3. A method according to claim 1, wherein the barriers comprise one or more lines of relatively low surface energy, and the one or more lines include breaks at one or more points thereof through which excess fluid can be controllably displaced out of the zone to the one or more selected locations.

4. A method of producing an electronic device by solution processing including depositing on a substrate two spaced channels of conductive material of controlled lateral width to form two electrodes of a transistor device, wherein the two spaced channels are formed by depositing fluid including the conductive material or a precursor thereto onto respective zones of a substrate surface defined by three longitudinal barriers including a central barrier and two outer barriers, wherein the two outer barriers are structured to facilitate controlled spillage of excess fluid out of the zones away from the central barrier and thereby avoid undesirable interconnection of the two channels.

5. A method according to claim 1, wherein the barriers are regions of relatively lyophobic surface energy.

6. A method according to claim 1, wherein the deposition of fluid onto said zone is carried out by localised deposition of droplets of the fluid onto the zone.

7. A method according to claim 6, wherein the deposition of fluid onto said zone is carried out by an ink-jet printing technique.

8. A substrate for use in the production of an electronic device by solution processing, the substrate having provided on a surface thereof at least two opposed barriers for together controlling the spread of fluid including a device material or a precursor thereto deposited on a zone therebetween, at least one of the barriers structured so as to facilitate controlled spillage of excess fluid out of the zone to one or more selected locations.

9. A substrate for producing by solution processing an electronic device including two spaced conductive channels of controlled lateral width as two electrodes of a transistor device, wherein the substrate surface includes three longitudinal barriers comprising a central barrier and two outer barriers which together define two longitudinal zones for receiving fluid including a conductive material or a precursor thereto to form the two spaced conductive channels of controlled lateral width, and wherein the two outer barriers are structured so as to facilitate controlled spillage of excess fluid out of the zones away from the central barrier and thereby avoid interconnection of the two channels.

10. A substrate according to claim 6, wherein the barriers are regions of relatively lyophobic surface energy.

11. A method of producing an electronic device by solution processing including longitudinally depositing fluid containing a device material or a precursor thereto on a patterned substrate to form a plurality of spaced longitudinal channels of said device material of controlled lateral width, wherein the substrate is patterned such that at least one lateral connection between at least one pair of adjacent channels is formed at at least one selected location without the need to carry out any lateral deposition of said fluid.

12. A method according to claim 11, wherein the substrate is patterned with an array of longitudinal lines of low surface energy defining longitudinal high surface energy zones therebetween, and wherein one or more of the lines are provided with breaks at one or more locations so as to allow at least one pair of adjacent longitudinal channels to be joined laterally at one or more selected locations.

13. A method according to claim 12, wherein the breaks are designed such that the movement of fluid therethrough between adjacent high surface energy zones selectively occurs under the weight of an excess of fluid on one or more of the high surface energy zones, whereby the lateral connection between the two high surface energy zones can be formed whilst at the same time ensuring the required level of fluid on the two high surface energy zones.

14. A substrate for use in producing an electronic device by solution processing, the substrate patterned to define at least three adjacent longitudinal zones for forming at least three adjacent longitudinal channels of device material of a controlled width by the longitudinal deposition in the at least three zones of fluid including such device material or a precursor thereto, and wherein the substrate is further patterned such that, in use, longitudinal deposition of said fluid at corresponding locations in each of the three adjacent zones can result in a lateral connection automatically formed between only two of the resulting three longitudinal channels.

15. A substrate according to claim 14 including a parallel array of longitudinal barriers for defining the at least three longitudinal zones, adjacent barriers being provided with breaks at offset positions such that longitudinal deposition of said fluid at corresponding locations in each of the three adjacent zones can result in a lateral connection automatically formed between only two of the resulting three longitudinal channels.

16. A substrate according to claim 15, wherein the array of longitudinal barriers includes a regular array of breaks at offset positions.

17. A substrate according to claim 15, wherein the breaks are designed such that the movement of fluid therethrough between adjacent high surface energy zones selectively occurs under the weight of an excess of fluid on one or more of the high surface energy zones, whereby the lateral connection between the two high surface energy zones can be formed whilst at the same time ensuring the required level of fluid on both the two high surface energy zones.

18. A method as in claim 1, wherein said electronic device is an electronic switching device, preferably an integrated transistor circuit.

19. A method as in claim 11, wherein said electronic device is an electronic switching device, preferably an integrated transistor circuit.

20. A substrate as in claim 8, wherein said electronic device is an electronic switching device, preferably an integrated transistor circuit.

21. A substrate as in claim 14, wherein said electronic device is an electronic switching device, preferably an integrated transistor circuit.
